(19) United States
(12) Patent Application Publication
(10) Pub. No.: US 2018/0138890 A1
(43) Pub. Date: May 17, 2018

(54) MULTIPLEXER

(71) Applicant: SNAPTRACK, INC., San Diego, CA (US)

(72) Inventor: Franz KUBAT, München (DE)

(21) Appl. No.: 15/574,325

(22) PCT Filed: May 17, 2016
(86) PCT No.: PCT/EP2016/061028

§ 371 Date: Nov. 15, 2017

(30) Foreign Application Priority Data
May 29, 2015 (DE) 10 2015 108 511.9

(51) Int. Cl. H03H 9/64; H03H 9/72; H03H 9/02; H03H 9/70; H04L 5/14

(52) U.S. Cl. CPC H03H 9/6489; H03H 9/725; H04L 5/1461; H03H 9/706; H03H 9/02228

(57) ABSTRACT

The multiplexer operates with acoustic waves. The multiplexer comprises an antenna connector (ANT) for coupling the multiplexer to at least one antenna, at least one transmission connector (TxC), at least one reception connector (RxC), and a common connector (CC). Furthermore, the multiplexer includes at least one reception path, which is interconnected between the at least one reception connector (RxC) and the common connector (CC) and which comprises a reception filter (RX), operating with acoustic waves. The multiplexer includes at least one transmission path, which is interconnected between the at least one transmission connector (TxC) and the common connector (CC) and which comprises a transmission filter (TX), operating with acoustic waves A multiplexer. Furthermore, the multiplexer includes at least one mirror network (PH) which is configured and arranged to rotate a phase of an antenna-side output reflection coefficient (S22) of the at least one transmission path and/or of the at least one reception path in a predetermined frequency band such that an absolute value of the respective output reflection coefficient in the predetermined frequency band exceeds a predetermined limit value and signals are thus reflected in the predetermined frequency band such that an interference mode excitation in the transmission filter (TX) of the at least one transmission path or in the reception filter of the at least one reception path (RX) is suppressed or reduced.

The invention relates to a multiplexer operating with acoustic waves.

Multiplexers comprise at least one transmission signal path each having a transmission filter and at least one reception signal path, each having a reception filter. In general, it is not readily possible to interconnect these two filters directly with a common connection, for example an antenna connector. Therefore, a matching circuit is commonly provided between the transmission filter and the reception filter in multiplexers. The matching circuit is dimensioned to increase the isolation between the transmission signal path and the reception signal path to values that meet the predetermined specifications. In this case, the attenuation of the interference signal components is thus optimized.

Intermodulation effects in multiplexers also play a role. In multiplexers, and especially in duplexers, those intermodulation products are problematic that arise at an antenna input and are within a reception band or in the vicinity of the reception band. They “block” the reception signal path since they cannot be simply filtered out by filtering measures. Otherwise, the usable reception frequency would also be destroyed. Such undesired intermodulation products may arise, in particular, in duplexers by the multiplication of transmission signals with a blocking signal received externally through the antenna. In the case of a duplexer, the reception passband associated with a transmission signal is relatively close to, usually above, the transmission passband. As a result, while harmonics of the transmission signal do not fall into the own reception passband, the intermodulation products from the transmission signal and an externally received signal do. In this context, DE 10 2012 108 030 A1 discloses a multiplexer operating with acoustic waves and having one or a plurality of blocking paths. The blocking path(s) allow for frequency components that can cause undesired intermodulation effects to be suppressed. In this case, the attenuation of the interference signal components is optimized as well.

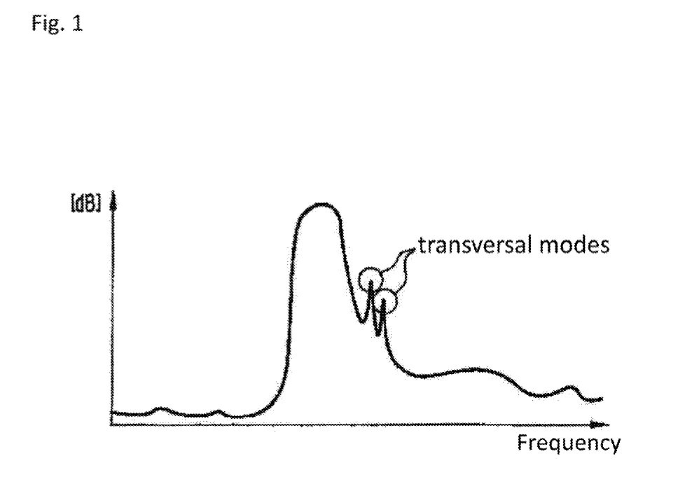

As is known, interfering modes, such as waveguide modes, plate modes, love modes, and shear modes, occur as undesirable effects as well, particularly in acoustic waveguide filters. The waveguide modes appear, for example, as the filter transmission curve of a surface acoustic wave filter according to FIG. 1 shows, as narrow-band peaks, for example, in the upper blocking region of the filter, with the height and frequency position of these peaks being dependent on an acoustic aperture of the filter. In the case of multiplexers operating with acoustic waves, undesirable performance limitations are therefore encountered. In a transmission filter of the multiplexer operating with acoustic waves, such interfering modes are excited, for example, by the reception signals that enter the transmission path.

The object of the invention is to provide a multiplexer operating with acoustic waves, having low acoustic interference mode excitation.

The object is achieved by the features of the independent claim. Advantageous developments of the invention are characterized in the dependent claims.

The invention is characterized by a multiplexer operating with acoustic waves. The multiplexer comprises an antenna connector for coupling the multiplexer to at least one antenna, at least one transmission connector, at least one reception connector, and a common connector. Furthermore, the multiplexer includes at least one reception path, which is interconnected between the at least one reception connector and the common connector and which comprises a reception filter operating with acoustic waves. The multiplexer includes at least one transmission path, which is interconnected between the at least one transmission connector and the common connector and which comprises a transmission filter operating with acoustic waves. Furthermore, the multiplexer includes at least one mirror network which is configured and arranged to rotate a phase of an antenna-side output reflection coefficient of the at least one transmission path and/or of the at least one reception path in a predetermined frequency band such that an absolute value of the respective output reflection coefficient in the predetermined frequency band exceeds a predetermined limit value and signals are thus reflected in the predetermined frequency band such that an interference mode excitation in the transmission filter of the at least one transmission path or in the reception filter of the at least one reception path is suppressed or reduced.

The mirror network is used in the multiplexer to rotate a phase of the antenna-side output reflection coefficient of the at least one transmission path and/or of the at least one reception path in the predetermined frequency band such that the absolute value of the respective output reflection coefficient in the predetermined frequency band exceeds the predetermined limit value and signals are thus reflected in the predetermined frequency band such that an interference mode excitation in the transmission filter of the at least one transmission path or in the reception filter of the at least one reception path is suppressed or reduced.

For the reception filters and/or transmission filters operating with acoustic waves, interference modes may occur depending on the dimensioning and excitation of the respective filters. For example, the filters may operate with a Rayleigh wave as the main wave. In this case love modes and shear modes, in particular, may occur as interference modes.

The predetermined frequency band is preferably determined by a respective position of the modes. Advantageously, a respective phase rotation of the mirror network prevents, or at least greatly reduces, an interference mode excitation in the at least one transmission path and/or the at least one reception path. By the targeted dimensioning of the mirror network in order to optimize the reflection, the reflection mode excitation can be prevented or at least reduced. The mirror network allows for a targeted phase rotation of the antenna-side output reflection coefficient of the at least one transmission path and/or the at least one reception path.

Preventing or reducing the mode excitation allows for a simultaneous improvement of the selection in the predetermined frequency band.

The improved output reflection makes it possible, for example, that no, or virtually no, interfering signals exciting the modes enter the at least one transmission path. The aim is not to attenuate or suppress the signals exciting interfering modes in the at least one transmission path, but instead to prevent such interfering, mode-exciting signals from reaching the at least one transmission path in the first place.

Experiments have shown that improved attenuation of the interfering, mode-exciting signals in the given frequency band is in many cases not sufficient and does not result in the same Improvement of results as the improvement in the reflection of the interfering, mode-exciting signals by the phase rotation since the lack of reflection causes a deterioration of the insertion loss in the counterband.

The term multiplexer relates to a frequency divider having at least one common connector, which may be an antenna connector, as well as a number of m Tx signal paths and n Rx signal paths, where m and n are integers ≥1. In particular, the multiplexer may be a duplexer with a Tx path and an Rx path.

The multiplexer operates with acoustic waves. These may be, for example, surface acoustic waves (SAWs), bulk acoustic waves (BAWs), or guided bulk acoustic waves (GBAWs).

It is also possible for the respective transmission filter to operate with one of the indicated types of acoustic waves, while the respective reception filter operates with a different type of acoustic waves.

According to an advantageous embodiment, the mirror network is connected in a transmission path on the antenna side upstream of the transmission filter and the mirror network is configured to rotate a phase of the antenna-side output reflection coefficient of the at least one transmission path in the predetermined frequency band such that the absolute value of the output reflection coefficient in the predetermined frequency band exceeds the predetermined limit value and signals are thus reflected in the predetermined frequency band such that an interference mode excitation in the transmission filter of the at least one transmission path is suppressed or reduced. Advantageously, this allows for a very flexible design so that a quadplexer, for example, may have excellent transmission characteristics.

According to another advantageous embodiment, the mirror network is interconnected between the antenna connector and the common connector.

According to another advantageous embodiment, the at least one reception filter and/or the at least one transmission filter operates with surface acoustic waves, with bulk acoustic waves, or with guided bulk acoustic waves. This has the advantage that a high filter selection can be realized.

According to another advantageous embodiment, the mirror network includes a resonator which operates with acoustic waves. Advantageously, this allows for a flexible design and cost-effective manufacturing of the multiplexer.

According to another advantageous embodiment, the mirror network includes a serial branch resonator and an inductive element connected in parallel with the serial branch resonator. Advantageously, additional design freedoms can be utilized.

According to another advantageous embodiment, the mirror network includes a serial branch capacitance and an inductive element connected in parallel with the serial branch capacitance.

According to another advantageous embodiment, the mirror network includes a serial branch resonator and an inductive element, connected in parallel with the serial branch resonator, as well as a parallel-branch resonator. Advantageously, additional design freedoms can be utilized.

According to another advantageous embodiment, the multiplexer further comprises one or more additional transmission paths, each having an additional transmission filter, and one or more additional reception paths, each having an additional reception filter. Thus, in addition to a duplexer, it is also easily possible to obtain triplexers, quadplexers, and so on.

According to another advantageous embodiment, the multiplexer is a diplexer or triplexer or quadplexer or quintplexer.

Exemplary embodiments of the invention are explained in the following with reference to the schematic drawings.

Shown are:

FIG. 1 shows a filter transmission curve of a surface acoustic wave filter,

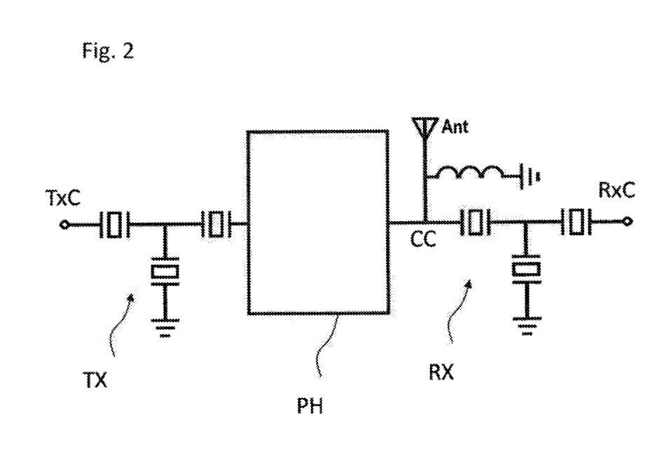

FIG. 2 shows a first exemplary embodiment of a multiplexer operating with acoustic waves,

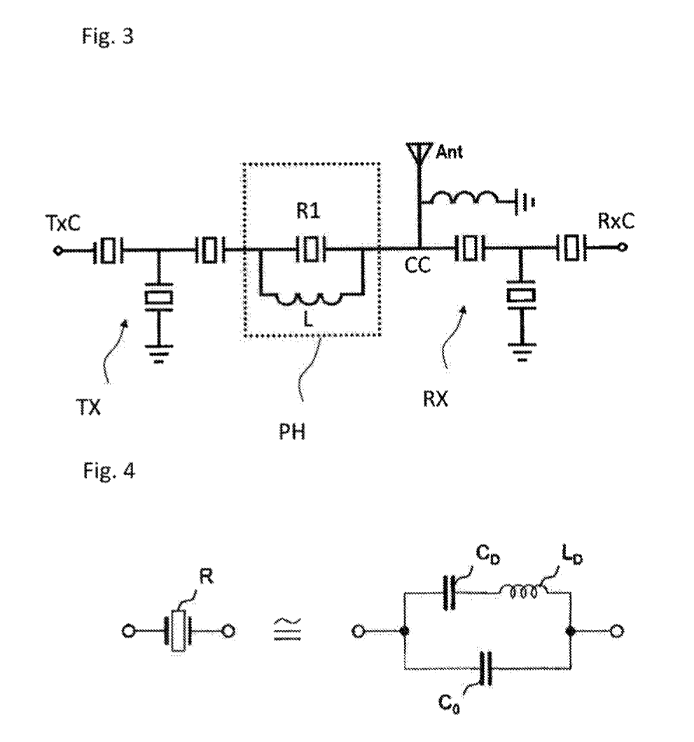

FIG. 3 shows a first exemplary embodiment of a mirror network,

FIG. 4 shows an equivalent circuit diagram of an electroacoustic resonator,

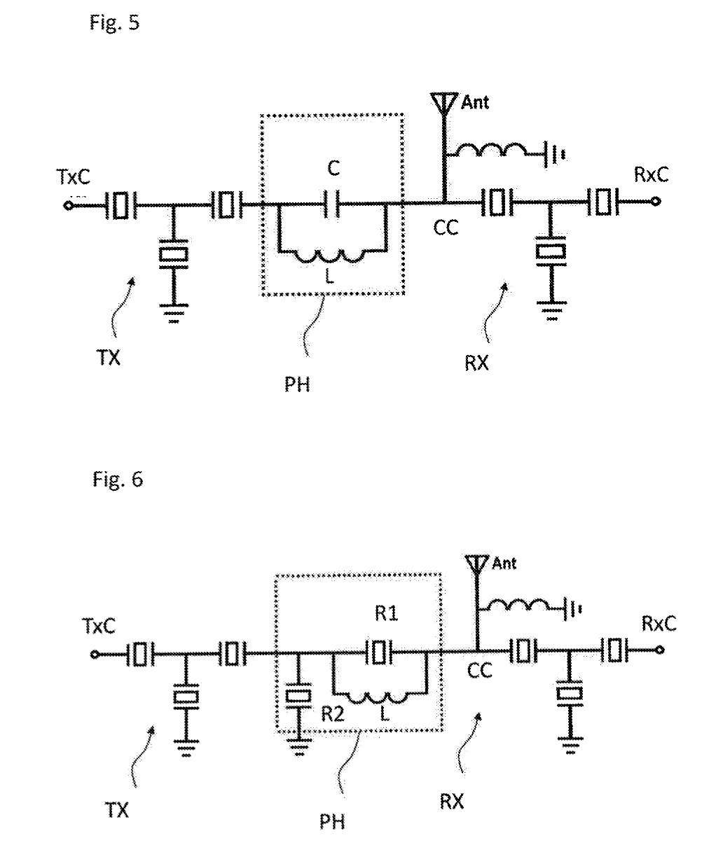

FIG. 5 shows a second exemplary embodiment of a mirror network,

FIG. 6 shows a third exemplary embodiment of a mirror network,

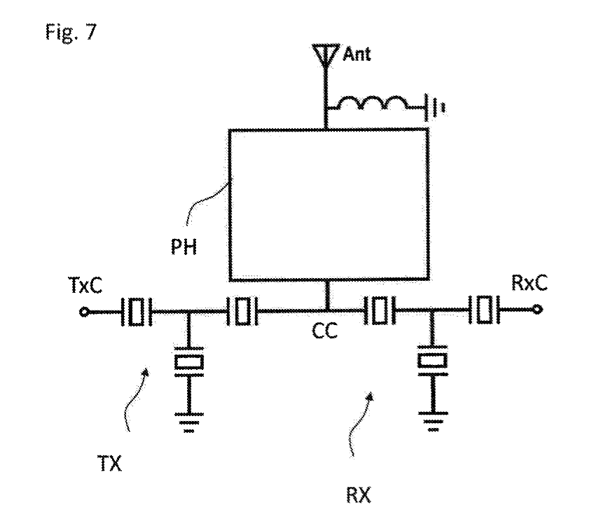

FIG. 7 shows a second exemplary embodiment of a multiplexer operating with acoustic waves,

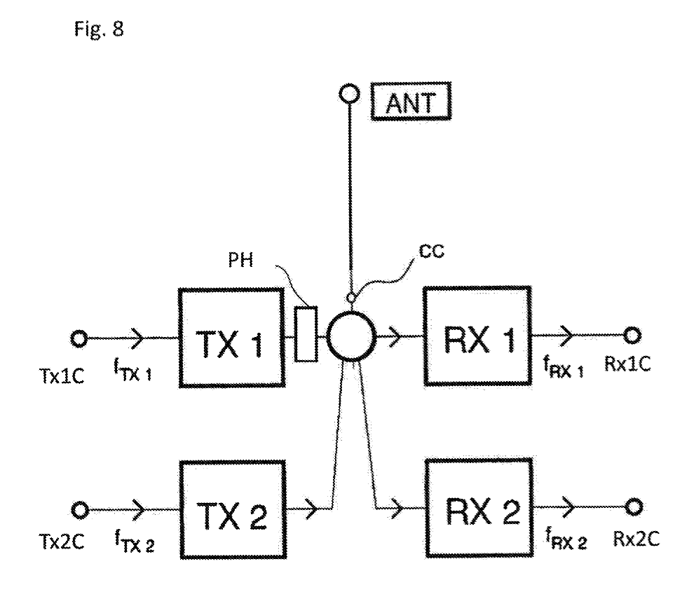

FIG. 8 shows a third exemplary embodiment of the multiplexer operating with acoustic waves,

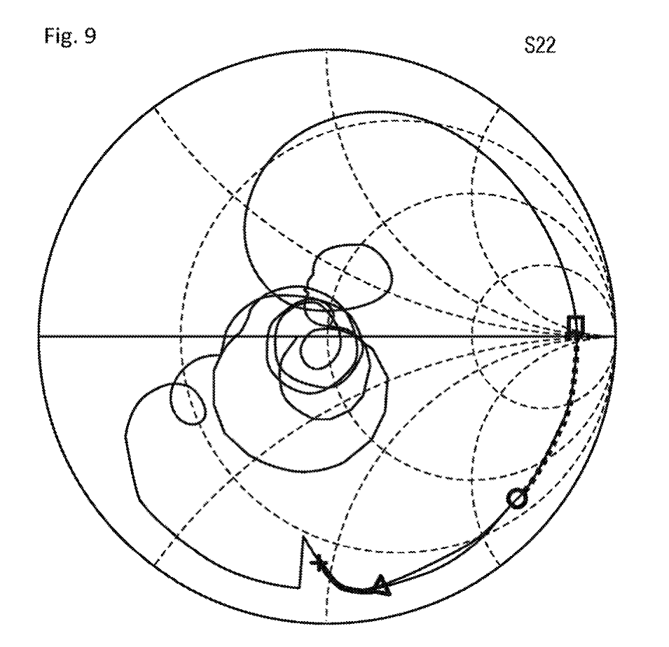

FIG. 9 shows an exemplary profile of the antenna-side output reflection coefficient of a first transmission path,

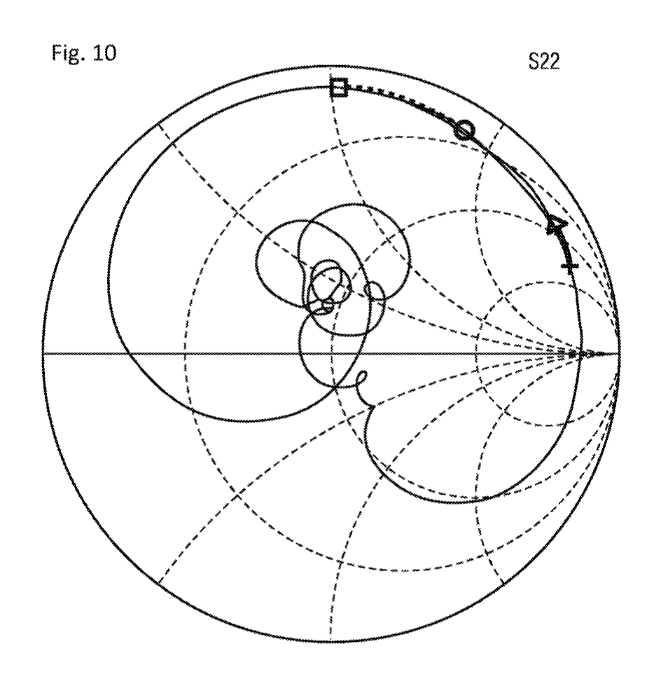

FIG. 10 shows another exemplary profile of the antenna-side output reflection coefficient of the first transmission path,

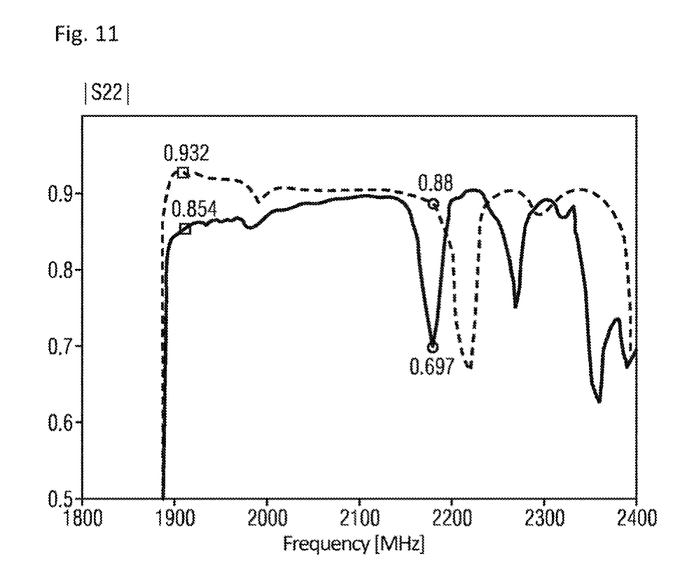

FIG. 11 shows an exemplary absolute value profile of the antenna-side output reflection coefficient of the first transmission path,

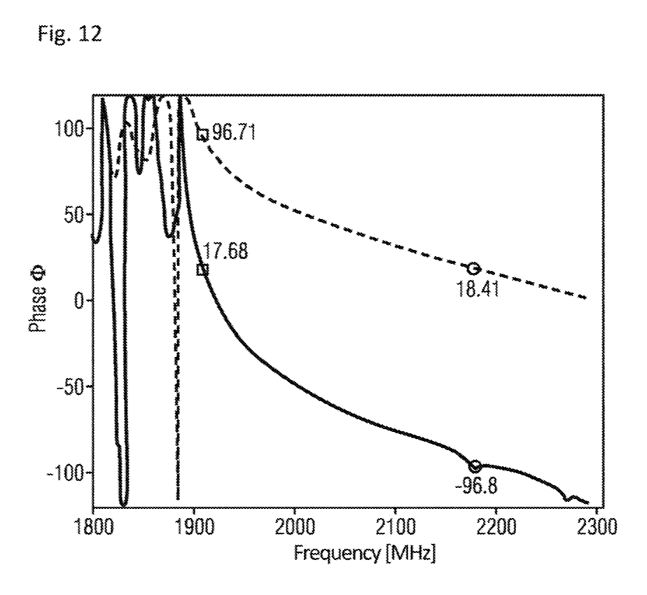

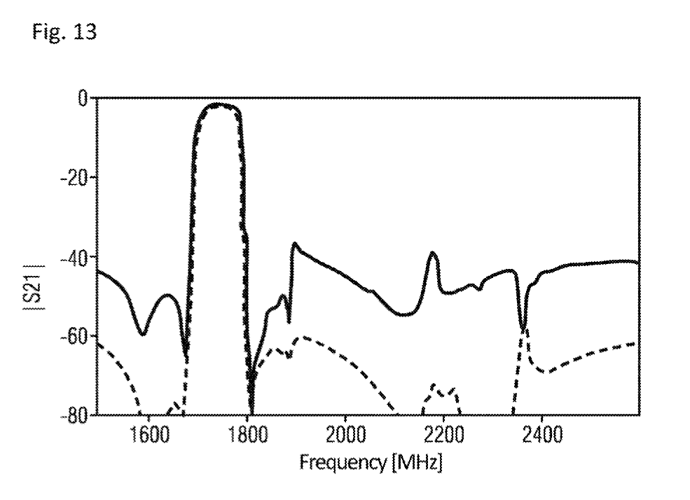

FIG. 12 shows an exemplary phase profile of the antenna-side output reflection coefficient of the first transmission path, and

FIG. 13 shows the absolute value profile of the forward transmission coefficient of the first transmission path.

Elements of the same construction or function are labelled with the same reference numerals across the figures.

FIG. 2 shows a first exemplary embodiment of a multiplexer operating with acoustic waves. The multiplexer comprises, for example, a transmission connector TxC, a reception connector RxC, and a common connector CC. Furthermore, the multiplexer comprises a reception path, which is interconnected between the reception connector RxC and the common connector CC and which includes a reception filter RX, operating with acoustic waves. The multiplexer further comprises a transmission path which is interconnected between the first transmission connector Tx1C and the common connector CC and which includes a transmission filter TX, operating with acoustic waves.

The reception filter RX and/or the transmission filter TX comprises, for example, a T-circuit having resonators, operating with acoustic waves, such as SAW resonators, BAN resonators, or GBAW resonators.

Alternatively, or additionally, the reception filter RX and/or the transmission filter TX may comprise, for example, a so-called π-circuit of resonators.

In the exemplary embodiment shown in FIG. 2, the multiplexer includes a mirror network PH, which is connected upstream of the transmission filter TX in the transmission path on the antenna side. The mirror network PH is configured to rotate a phase of the antenna-side output reflection coefficient S22 of the transmission path in the predetermined frequency band such that an absolute value of the output reflection coefficient S22 in a predetermined frequency band exceeds a predetermined limit value and signals received at the antenna side are thus reflected in the predetermined frequency band such that an interference mode excitation in the transmission filter TX is prevented or reduced.

FIG. 3 shows the first exemplary embodiment of the multiplexer of FIG. 2 with a first exemplary embodiment of the mirror network PH. In this case, the mirror network PH includes a resonator R. The resonator R is formed, for example, as an electroacoustic resonator. The mirror network PH includes, for example, a serial branch resonator R1 and an inductive element connected in parallel with the serial branch resonator R1.

FIG. 4 shows the equivalent circuit diagram ECD of the electroacoustic resonator R. The equivalent circuit diagram comprises a static capacitance C0 and, in parallel therewith, a series circuit consisting of a dynamic capacitance CD and a dynamic inductance LD. At frequencies far from the acoustic operating frequency, the resonator R essentially presents itself as a capacitive element with the static capacitance C0. The dynamic capacitance CD and the dynamic inductance LD are essentially negligible. The behavior is different in the operating range of the resonator. In that case, the dynamic capacitance CD and the dynamic inductance LD essentially dominate the behavior of the resonator, while the static capacity C0 plays a subordinate role. Depending on the dimensioning of the electroacoustic resonator R and the definition of its operating range, a resonator R can thus be operated as a pure capacitive element or as a pure electroacoustic element or as a mixed type of the two elements so that the resonator R may be adapted. To provide the resonator R, essentially no additional process steps are required for production so that the proposed multiplexer can be produced without additional complexity.

FIG. 5 shows the first exemplary embodiment of the multiplexer of FIG. 2 with a second exemplary embodiment of the mirror network PH. In this case, the mirror network PH includes, for example, a serial branch capacitance C and an inductive element L connected in parallel with the serial branch capacitance C.

FIG. 6 shows the first exemplary embodiment of the multiplexer of FIG. 2 with a third exemplary embodiment of the mirror network PH. In this case, the mirror network PH includes two resonators. The resonators are configured, for example, as electroacoustic resonators. The mirror network PH includes, for example, a serial branch resonator R1 and an inductive element L connected in parallel with the serial branch resonator R1. Furthermore, the mirror network PH includes a parallel-branch resonator R2.

FIG. 7 shows a second exemplary embodiment of the multiplexer operating with acoustic waves. In contrast to the exemplary embodiment shown in FIG. 2, the mirror network PH is interconnected between an antenna connector ANT and the common connector CC.

FIG. 8 shows a third exemplary embodiment of the multiplexer operating with acoustic waves. In this case, the multiplexer is formed as a quadplexer.

The multiplexer includes a first transmission connector Tx1C, a first reception connector Rx1C, a second transmission connector Tx2C, and a second reception connector Rx2C as well as a common connector CC. Furthermore, the multiplexer comprises a first reception path, which is interconnected between the reception connector RxC1 and the common connector CC, and includes a first reception filter RX1, operating with acoustic waves, and a first reception frequency bandpass band fRX1. The multiplexer includes a first transmission path, which is associated with the first reception path and which is interconnected between the first transmission connector Tx1C and the common connector CC and which includes a first transmission filter TX1, operating with acoustic waves and having a first transmission frequency bandpass band fTX1.

The multiplexer comprises a second reception path, which is interconnected between the second reception connector Rx2C and the common connector CC and includes a second reception filter RX2, operating with acoustic waves and having a second reception frequency bandpass band fRX2. The multiplexer includes a second transmission path, which is associated with the second reception path and which is interconnected between the first transmission connector Tx2C and the common connector CC and which includes a second transmission filter TX2, operating with acoustic waves and having a second transmission frequency bandpass band fTX2.

In the exemplary embodiment shown in FIG. 8, the multiplexer includes a mirror network PH, which is connected upstream of the first transmission filter TX1 in the first transmission path on the antenna side.

The mirror network PH is configured, for example, to rotate the phase of the antenna-side output reflection coefficient S22 of the transmission path in a predetermined frequency band, which is equal to or closer to the second reception frequency bandpass band fRX2 of the second reception filter RX2, such that an absolute value of the output reflection coefficient S22 in a predetermined frequency band exceeds a predetermined limit value and signals received at the antenna side are thus reflected in the predetermined frequency band such that an interference mode excitation in the first transmission filter TX1 is prevented or reduced.

FIG. 9 exemplarily shows a profile of the antenna-side output reflection coefficient S22 of the first transmission path for the quadplexer according to FIG. 8 without a mirror network PH. In this case, the profile of the output reflection coefficient S22 for the second reception frequency-passband fRX2 of the second reception filter RX2 is marked as a dotted line, and is marked as a dashed line for the second transmission frequency-passband fTX2 of the second transmission filter TX2.

The profile of the output reflection coefficient S22 has a narrow-band peak, which is attributable to a mode excitation, in particular in the region of the second reception frequency passband fRX2 of the second reception filter RX2. This results in increased adaptation losses in the counterband, i.e., in the second reception frequency passband fRX2, of the second reception path since the signals are no longer available to the second reception path.

FIG. 10 exemplarily shows a profile of the antenna-side output reflection coefficient S22 of the first transmission path for the quadplexer according to FIG. 8 with a mirror network PH. In this case, the profile of the output reflection coefficient S22 for the second reception frequency-passband fRX2 of the second reception filter RX2 is marked as a dotted line, and is marked as a dashed line for the second transmission frequency-passband fTX2 of the second transmission filter TX2.

The phase position of the output reflection coefficient S22 is rotated by the mirror network PH and the narrow-band peak due to mode excitation disappears.

FIG. 11 shows the absolute value profile of the antenna-side output reflection coefficient S22 of the first transmission path for the quadplexer according to FIG. 8 without a mirror network PH (solid line) and with a mirror network PH (dashed line).

FIG. 12 shows the phase profile of the antenna-side output reflection coefficient S22 of the first transmission path for the quadplexer according to FIG. 8 without a mirror network PH (solid line) and with a mirror network PH (dashed line).

Both in FIG. 11 and FIG. 12, it is apparent that an interference mode excitation can be prevented, or at least greatly reduced, in particular in the first transmission filter TX1, by the phase rotation of the mirror network PH in the first transmission path.

The improved output reflection makes it possible that no, or virtually no, interfering signals exciting the modes enter the first transmission path. The aim is not to attenuate or suppress the signals exciting interfering modes in the first transmission path, but instead to prevent such interfering, mode-exciting signals from reaching the first transmission path in the first place.

FIG. 13 shows the absolute value profile of the forward transmission coefficient S21 of the first transmission path for the quadplexer according to FIG. 8 without a mirror network PH (solid line) and with a mirror network PH (dashed line). It is apparent that the forward transmission coefficient S21 in the counterband, that is to say in the region of the second reception frequency passband fRX2, and in the region of the second transmission frequency passband, is also significantly improved due to the prevention or reduction of the interference mode excitation.

### LIST OF REFERENCE SIGNS

ANT Antenna connector
C0 static capacity
CC common connector
CD dynamic capacity
ECD equivalent circuit diagram
fRX1 first reception frequency passband
fRX2 second reception frequency passband
fTX1 first transmission frequency passband
ftX2 second transmission frequency passband
L inductive element
LD dynamic inductance
PH mirror network
R resonator
R1 serial branch resonator
R2 parallel branch resonator
RX reception filter
RX1 first reception filter
Rx1C first reception connector
RX2 second reception filter
Rx2C second reception connector
RxC reception connector
S21 forward transmission coefficient
S22 output reflection coefficient
TX Transmission filter
TX1 first transmission filter
Tx1C first transmission connector
TX2 second transmission filter
Tx2C second transmission connector
TxC transmission connector
Φ phase of the output reflection coefficient

1. A multiplexer operating with acoustic waves, including
an antenna connector (ANT) for coupling the multiplexer to at least one antenna,
at least one transmission connector (TxC), at least one reception connector (RxC), and a common connector (CC),
at least one reception path, which is interconnected between the reception connector (RxC) and the common connector (CC) and which comprises a reception filter (RX), operating with acoustic waves,
at least one transmission path which is interconnected between the at least one transmission connector (TxC) and the common connector (CC) and which comprises a transmission filter (TX), operating with acoustic waves, and
at least one mirror network (PH) which is configured and arranged to rotate a phase of an antenna-side output reflection coefficient (S22) of the at least one transmission path and/or of the at least one reception path in a predetermined frequency band such that an absolute value of the respective output reflection coefficient (S22) in the predetermined frequency band exceeds a predetermined limit value and signals are thus reflected in the predetermined frequency band such that an interference mode excitation in the transmission filter (TX) of the at least one transmission path or in the reception filter (RX) of the at least one reception path is suppressed or reduced.

2. The multiplexer according to claim 1,
wherein the mirror network (PH) is connected in a transmission path on the antenna side upstream of the transmission filter (TX) and the mirror network (PH) is configured to rotate a phase of the antenna-side output reflection coefficient (S22) of the at least one transmission path in the predetermined frequency band such that the absolute value of the output reflection coefficient (S22) in the predetermined frequency band exceeds the predetermined limit value and signals are thus reflected in the predetermined frequency band such that an interference mode excitation in the transmission filter (TX) of the at least one transmission path is suppressed or reduced.

3. The multiplexer according to claim 1,
wherein the mirror network (PH) is interconnected between the antenna connector (ANT) and the common connector.

4. The multiplexer according to any of the preceding claims, wherein the at least one reception filter (RX) and/or the at least one transmission filter (TX) operates with surface acoustic waves, with bulk acoustic waves, or with guided bulk acoustic waves.

5. The multiplexer according to any of the preceding claims, wherein the mirror network (PH) includes a resonator (R), operating with acoustic waves.

6. The multiplexer according to any of the preceding claims, wherein the mirror network (PH) includes a serial branch resonator (R1) and an inductive element (L) connected in parallel with the serial branch resonator (R1).

7. The multiplexer according to any of the preceding claims, wherein the mirror network (PH) includes a serial branch capacitance (C) and an inductive element (L) connected in parallel with the serial branch capacitance (C).

8. The multiplexer according to any of the preceding claims, wherein the mirror network (PH) includes a serial branch resonator (R1) and an inductive element (L) connected in parallel with the serial branch resonator (R1), as well as a parallel branch resonator (R2).

9. The multiplexer according to any of the preceding claims, further comprising
one or more additional transmission paths, each having an additional transmission filter, and
one or more additional reception paths, each having an additional reception filter.

10. The multiplexer according to any of the preceding claims, wherein the multiplexer is a diplexer or triplexer or quadplexer or quintplexer.
